(19) United States
(12) Patent Application Publication
(10) Pub. No.: US 2021/0285106 A1
(43) Pub. Date: Sep. 16, 2021

(54) FILM DEPOSITION APPARATUS

(71) Applicant: Creative Coatings Co., Ltd., Tokyo (JP)

(72) Inventors: Eiji SATO, Tokyo (JP); Hitoshi SAKAMOTO, Nagaoka-shi (JP)

(73) Assignee: Creative Coatings Co., Ltd., Tokyo (JP)

(21) Appl. No.: 17/216,532

(22) Filed: Mar. 29, 2021

Related U.S. Application Data
(63) Continuation of application No. PCT/JP2019/036700, filed on Sep. 19, 2019.

(30) Foreign Application Priority Data
Oct. 18, 2018 (JP) 2018-196891

(51) Int. Cl. C23C 16/54; C23C 16/455

(52) U.S. Cl. CPC C23C 16/545; C23C 16/45563; C23C 16/45544

(57) ABSTRACT

A film deposition apparatus includes: a chamber having a film deposition gas introduced thereinto and exhausted therefrom, in which film deposition with the film deposition gas is performed on an object to be treated; and a film conveying part disposed in the chamber and conveying in a roll-to-roll manner a long film that is the object to be treated. The film conveying part includes: a rotatable roller with part of whose peripheral surface the long film comes into contact; and a nozzle pipe for spraying an inert gas onto a region of the roller, the region being not covered by the long film.

### CROSS REFERENCE TO RELATED APPLICATION

This application is a continuation of International Patent Application No. PCT/JP2019/036700, having an international filing date of Sep. 19, 2019, which designated the United States, the entirety of which is incorporated herein by reference. Japanese Patent Application No. 2018-196891 filed on Oct. 18, 2018 is also incorporated herein by reference in its entirety.

### BACKGROUND

The present disclosure relates to a film deposition apparatus that introduces gas into a chamber and deposits a film on a long film that is conveyed in the chamber in a roll-to-roll manner.

A film deposition apparatus performs sheet processing or batch processing in most cases; however, both of them cause an increase in complexity of a device for handling an object to be treated. Therefore, a long film that is an object to be treated is supplied in a roll-to-roll manner so as to perform continuous treatment, thereby improving throughput.

JP-A-2018-2386 discloses a film deposition apparatus that deposits a film on a long film that is conveyed in a vacuum chamber in a roll-to-roll manner. In this film deposition apparatus, four film deposition means, each of which deposits a metal film on one side of a long film by a metalizing method using a dry plating method, are disposed along a conveying path for the long film.

A film deposition apparatus that deposits a film on a long film that is conveyed in a roll-to-roll manner has been conventionally limited to an apparatus in which film deposition is performed only on part of all conveyance paths of a long film as described in JP-A-2018-2386.

### BRIEF DESCRIPTION OF THE DRAWINGS

FIG. 1 is a schematic cross-sectional view of a film deposition apparatus according to one embodiment of the disclosure.

FIG. 2 is a front view that illustrates a roller and a nozzle pipe that are disposed in a film conveyer.

FIG. 3 is a plan view of the nozzle pipe.

FIG. 4 is a view that illustrates the arrangement of the nozzle pipe illustrated in FIG. 3.

FIG. 5 is a cross-sectional view that illustrates a bearing part and a heater that are disposed in the film conveyer.

FIG. 6A is a plan view that illustrates a tension detection roller and a case surrounding the tension detection roller, and FIG. 6B is a cross-sectional view that illustrates the tension detection roller and the case.

### DESCRIPTION OF EXEMPLARY EMBODIMENTS

The following disclosure provides many different embodiments, or examples, for implementing different features of the provided subject matter. These are, of course, merely examples and are not intended to be limiting. In addition, the disclosure may repeat reference numerals and/or letters in the various examples. This repetition is for the purpose of simplicity and clarity and does not in itself dictate a relationship between the various embodiments and/or configurations discussed. Further, when a first element is described as being “connected” or “coupled” to a second element, such description includes embodiments in which the first and second elements are directly connected or coupled to each other, and also includes embodiments in which the first and second elements are indirectly connected or coupled to each other with one or more other intervening elements in between.

It is an object of some aspects of the disclosure to provide a film deposition apparatus capable of smoothly conveying a long film in a roll-to-roll manner even when the principle of film deposition on a long film supplied in a roll-to-roll manner is the principle of film deposition not limited to a part within a chamber.

(1) In accordance with one of some embodiments, there is provided a film deposition apparatus, comprising:

a chamber in which a target is provided and a film deposition gas for forming a film on the target is introduced thereinto and exhausted therefrom; and

a film conveyer disposed in the chamber and conveying in a roll-to-roll manner a long film that is the object;

wherein,

the film conveyer includes:

a rotatable roller in which the long film comes into contact with part of a peripheral surface of the roller; and

a nozzle pipe that sprays an inert gas onto the roller at a region being not covered by the long film.

According to the one aspect of the disclosure (1), the long film conveyed by the film conveyer in a roll-to-roll manner is brought into contact with a film deposition gas in the chamber so as to have a film deposited thereon. In this case, the film conveyer disposed in the chamber includes the rotatable roller, and a region of the roller, the region being not covered by the long film, is brought into contact with the film deposition gas. However, in one aspect of the disclosure, the region of the roller, the region being not covered by the long film, is sprayed with an inert gas through a nozzle pipe. Owing to the jetting pressure of this inert gas, the film deposition gas does not come into contact with the roller. This prevents a failure of conveyance, stop of conveyance, or pollution of the long film all of which can be caused by film deposition on the roller.

(2) In the one aspect of the disclosure (1), the film conveyer may further include: a bearing part that rotatably supports a shaft of the roller; and a heater that heats the bearing part up to a temperature at which the film deposition gas does not adhere to the shaft. By doing so, the function and effect of another aspect of the disclosure (4) described later can be exerted.

(3) In the one aspect of the disclosure (1) or (2), the film conveyer may further include:

a rotatable tension detection roller in which the long film comes into contact with part of a peripheral surface of the tension detection roller;

a tension sensor detecting tension based on external force acting on the tension detection roller; and

a case including a slit that exposes the part of the peripheral surface of the tension detection roller, and the case surrounding both the tension sensor the tension detection roller except the part of the peripheral surface;

wherein,

an inert gas is introduced into the case at a pressure higher than a pressure in the chamber. In this situation, the inert gas is introduced into the case at a pressure higher than a pressure in the chamber. By doing so, the function and effect of yet another aspect of the disclosure (5) described later can be exerted.

(4) In accordance with one of some embodiments, there is provided a film deposition apparatus, comprising:

a chamber in which a target is provided and a film deposition gas for forming a film on the target is introduced thereinto and exhausted therefrom; and

a film conveyer disposed in the chamber and conveying in a roll-to-roll manner a long film that is the object to be treated;

wherein,

the film conveyer includes:

a rotatable roller in which the long film comes into contact with part of a peripheral surface of the roller;

a bearing part rotatably supporting a shaft of the roller; and

a heater that heats the bearing part up to a temperature at which the film deposition gas does not adhere to the shaft.

According to the another aspect of the disclosure (4), the long film conveyed by the film conveyer in a roll-to-roll manner is brought into contact with the film deposition gas in the chamber so as to have a film deposited thereon. In this case, the film conveyer disposed in the chamber includes the bearing part that rotatably supports the shaft of the roller, and a supported part of the roller shaft may be brought into contact with the film deposition gas, thereby having a film deposited thereon. However, in the another aspect of the disclosure, the bearing part is heated by a heater and thereby the temperature of the shaft can be raised, through the bearing part, up to a temperature at which the film deposition gas does not adhere to the shaft. This prevents a failure of conveyance and stop of conveyance due to a failure of bearing all of which can be caused by film deposition on the roller shaft.

(5) In accordance with one of some embodiments, there is provided a film deposition apparatus, comprising:

a chamber in which a target is provided and a film deposition gas for forming a film on the target is introduced thereinto and exhausted therefrom;

a film conveyer disposed in the chamber and conveying in a roll-to-roll manner a long film that is the object to be treated;

wherein,

the film conveyer includes:

a rotatable tension detection roller in which the long film comes into contact with part of a peripheral surface of the tension detection roller;

a tension sensor detecting tension of the long film based on external force acting on the tension detection roller; and

a case including a slit that exposes the part of the peripheral surface of the tension detection roller, and the case surrounding both the tension sensor and the tension detection roller except the part of the peripheral surface;

wherein,

an inert gas is introduced into the case at a pressure higher than a pressure in the chamber.

According to the yet another aspect of the disclosure (5), the long film conveyed by the film conveyer in a roll-to-roll manner is brought into contact with the film deposition gas in the chamber so as to have a film deposited thereon. In this case, the film conveyer disposed in the chamber includes: a rotatable tension detection roller in which the part of the peripheral surface of the tension detection roller comes into contact with the long film; and a tension sensor. A region of the tension detection roller, the region being not covered by the long film, and the tension sensor may be brought into contact with the film deposition gas. However, in the yet another aspect of the disclosure, into a case that surrounds both the tension sensor and the tension detection roller except the part of the peripheral surface, the part being in contact with the long film, an inert gas is introduced at a pressure higher than a pressure in the chamber. As a result, a flow of an inert gas from inside the case into the chamber occurs and the film deposition gas does not enter the case. This prevents a detection failure and an erroneous detection both of which can be caused by film deposition on the tension detection roller and the tension sensor, thereby ensuring a smooth supply of the long film.

Hereinafter, a preferred embodiment of the disclosure will be described in detail. The embodiment described below does not limit unduly the scope of the claimed disclosure and all configurations described in the embodiment are not necessarily indispensable as means for solving the problem of the disclosure.

1. Overview of Film Deposition Apparatus

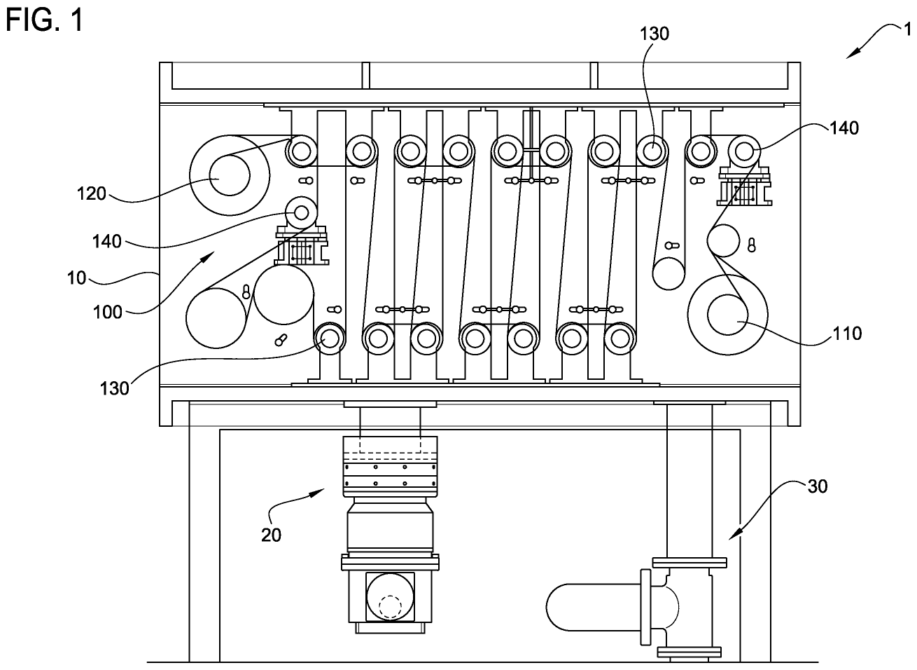

In FIG. 1, a film deposition apparatus 1 includes a chamber 10. The chamber 10 is, for example, a vacuum chamber; and an exhaust part 20 and a gas introduction part 30 are connected thereto. The exhaust part 20 evacuates the vacuum chamber 10 or exhausts an introduced gas. The gas introduction part 30 introduces one or a plurality of kinds of gases into the vacuum chamber 10. The plurality of kinds of gases can be simultaneously and/or selectively introduced. In addition, when, for example, the film deposition apparatus 1 is a plasma CVD apparatus, gas that has been turned into plasma outside the chamber 10 is introduced into the chamber 10 through the gas introduction part 30.

In the chamber 10, a film conveyer 100 that conveys a long film F that is an object to be treated is disposed. The film conveyer 100 conveys the long film F in a roll-to-roll manner. For this, the film conveyer 100 includes: an outfeed roller 110 that outfeeds the long film F that has been wound in a roll shape; and a winding roller 120 that winds up, into a roll shape, the long film F on which a film has been deposited. Between the outfeed roller 110 and the winding roller 120, a plurality of, for example, 19 rollers 130 having the same size and/or a different size and at least one, for example, two tension detection rollers 140 are disposed. Part of these rollers 110, 120, and 130 serves as a driving roller and the others serve as driven rollers. The film conveyer 100 intermittently conveys or continuously conveys the long film F according to a film deposition type.

The long film F is, during conveyance or stop, brought into contact with a deposition gas that is introduced into the chamber 10; and thereby has a film deposited thereon according to a film deposition principle. More specifically, this film deposition apparatus can deposit a film on any film deposition object at any position within the chamber 10, by contact with a film deposition gas that is introduced into the chamber 10. This type of film deposition principle may include a CVD in which a film is deposited by a vapor phase growth method and an ALD in which a film is deposited in an atomic layer unit. In a case of plasma CVD or the like that uses gas activated by using a plasma, an ultraviolet ray or the like as an energy source, the disclosure can be applied not only to a situation in which gas is locally activated within the chamber 10 but also to a situation in which gas activated outside the chamber 10 is introduced.

2. Prevention of Film Deposition on Roller

The roller 130 illustrated in FIG. 1 is a rotatable roller in which a part of the peripheral surface of the roller comes into contact with the long film F. More specifically, when the roller 130 is drivingly or drivenly rotated, each partial peripheral surface of the roller 130, the each partial peripheral surface being not in contact with the long film F, is brought into contact with a film deposition gas one after another. Accordingly, a film may be deposited on the whole peripheral surface of the roller 130.

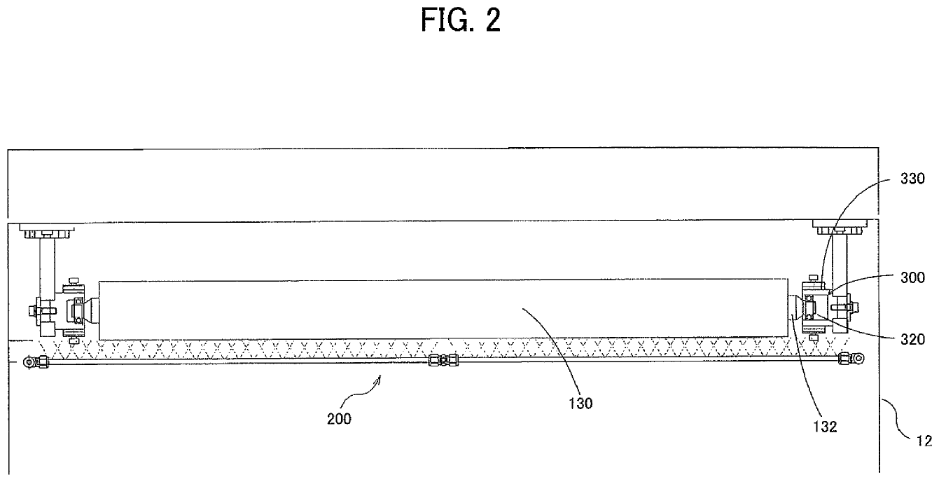

In order to prevent film deposition on the roller 130, a nozzle pipe 200 illustrated in FIG. 2 is disposed in parallel with a longitudinal axis of the roller 130 and at a position that faces a partial peripheral surface not covered by the long film F. The nozzle pipe 200 has jetting ports arranged along a longitudinal axis of the nozzle pipe 200. From the jetting ports of the nozzle pipe 200, an inert gas such as Ar or N₂ is jetted. A region of the roller 130, the region being not covered by the long film F, is sprayed with the inert gas through the nozzle pipe 200. Owing to the jetting pressure of this inert gas, the film deposition gas does not come into contact with the roller 130. This prevents a failure of conveyance, stop of conveyance, or contamination of the long film all of which can be caused by film deposition on the roller 130. On the other hand, since the inert gas does not affect film deposition using the film deposition gas on the long film F, film deposition on the long film F is not inhibited.

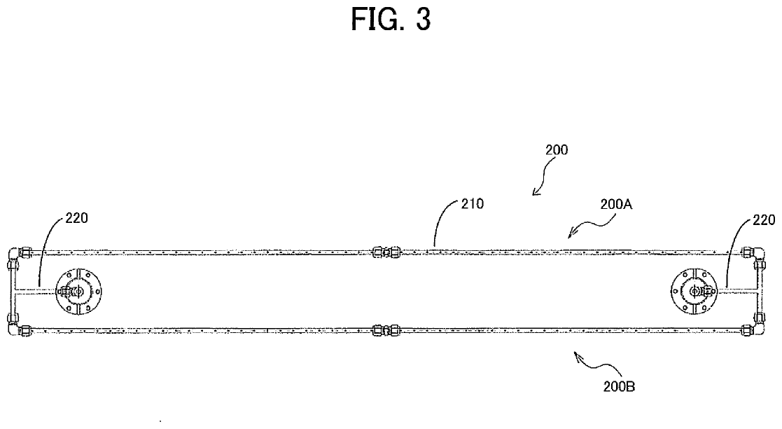

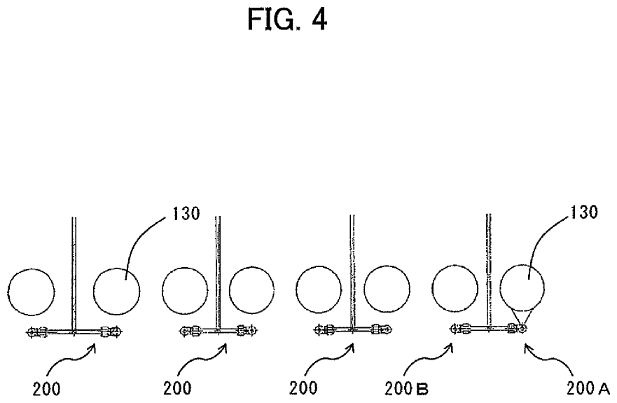

FIG. 3 is a plan view of the nozzle pipe 200. The nozzle pipe 200 illustrated in FIG. 3 prevents film deposition on two rollers 130 that are adjacent to each other in the chamber 10, as illustrated in FIG. 4. For this, the nozzle pipe 200 is, for example, disposed in a loop shape and jetting ports 210 are arranged on two parallel longitudinal axes 200A and 200B. In an example of FIG. 3, a gas supply pipe 220, 220 is coupled to both end parts in a longitudinal direction of the nozzle pipe 200, and the nozzle pipe 200 is supplied with an inert gas from both ends in the longitudinal direction. Thus, from the jetting ports 210 on the longitudinal axis 200A of the nozzle pipe 200 and the jetting ports 210 on the longitudinal axis 200B, an inert gas can be sprayed onto two rollers 130 (see FIG. 4). The nozzle pipe 200 may have one longitudinal axis that faces one roller 130. Besides, it may have three or more longitudinal axes and spray an inert gas onto three or more rollers 130. When the nozzle pipe 200 is formed in a loop shape, interference with the long film F can be prevented by having the long film F conveyed so as to pass inside and outside the loop.

3. Prevention of Film Deposition on Roller Shaft

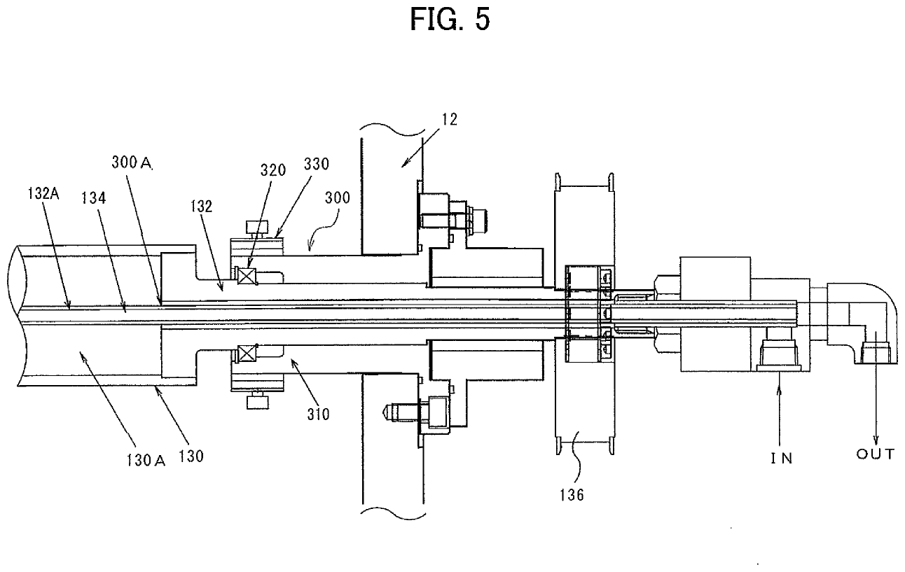

The roller 130 illustrated in FIG. 1 includes a bearing part 300 by which a shaft 132 of the roller 130 is rotatably supported, as illustrated in FIG. 5. The bearing part 300 includes a bearing body 310 that protrudes inside and outside of a chamber wall 12 of the chamber 10. The bearing body 310 is airtightly fixed to the chamber wall 12. At a tip end of the bearing body 310 that protrudes inside the chamber 10, a bearing 320 supporting the shaft 132 is disposed.

Part of the shaft 132 of the roller 130, the part being supported by the bearing 320, is brought into contact with a film deposition gas, thereby causing film deposition thereon. In order to prevent this film deposition, a heater, for example, a band heater 330, is arranged, for example, around where the bearing 320 is disposed, as illustrated in FIG. 5. The temperatures of the bearing part 300 and the shaft 132 are raised by the heater 330, so that a temperature range that does not allow the film deposition gas to be adhered to the shaft 132 can be kept. This prevents a failure of conveyance and stop of conveyance due to a failure of bearing that can be caused by film deposition on the shaft 132 of the roller 130.

Here, the temperature range set by the heater 330, the temperature range not allowing a film deposition gas to be adhered to the shaft 132, differs according to a film deposition type. For example, for Tris (Timethylamino) Silane (TDMAS: HSi[N(CH₃)₂]₃), 50 to 150° C. and for Trimethyl Aluminum (TMA: Al(CH₃)₃), 80 to 200° C.

As in FIG. 5, a hollow part 130A is arranged in the roller 130 and a hollow part 132A is arranged in the shaft 132; and both the hollow parts 130A and 132A communicate with each other. In both the hollow parts 130A and 132A, an introduction pipe 134 for a coolant, for example, cooling water is disposed. Cooling water supplied from the introduction pipe 134 is introduced into the hollow part 130A of the roller 130 and cools the roller 130. In order to drain water from the hollow part 130A of the roller 130, the hollow part 132A formed in the shaft 132 is used as a cooling water lead-out path. Here, by cooling the roller 130, a surface of the film F, the surface coming into contact with the roller 130, can be kept at a low temperature while the bearing part 300 is heated by the heater 330. Note that in FIG. 5, a pulley 136 is arranged on the shaft 132 that has been taken outside the chamber wall 12. By belt-driving this pulley 136, the roller 130 is allowed to function as a driving roller, and in addition, dust during driving does not enter the chamber 10.

When the roller 130 is a driven roller, the pulley 136 is unnecessary. In FIG. 2, the roller 130 that is a driven roller is illustrated. In this case, the bearing part 300 is supported hanging down in the chamber 10. Also around the bearing 320 of this bearing part 300, a heater, for example, the band heater 330 is provided.

4. Prevention of Film Deposition on Tension Detection Roller and Tension Sensor

Each of the tension detection rollers 140 illustrated in FIG. 1 is a rotatable roller in which part of the peripheral surface of the each roller 140 comes into contact with the long film F. More specifically, when the tension detection roller 140 is drivenly rotated, each partial peripheral surface of the tension detection roller 140, the each partial peripheral surface being not in contact with the long film F, is brought into contact with a film deposition gas one after another. As a result, a film may be deposited on the whole peripheral surface of the tension detection roller 140.

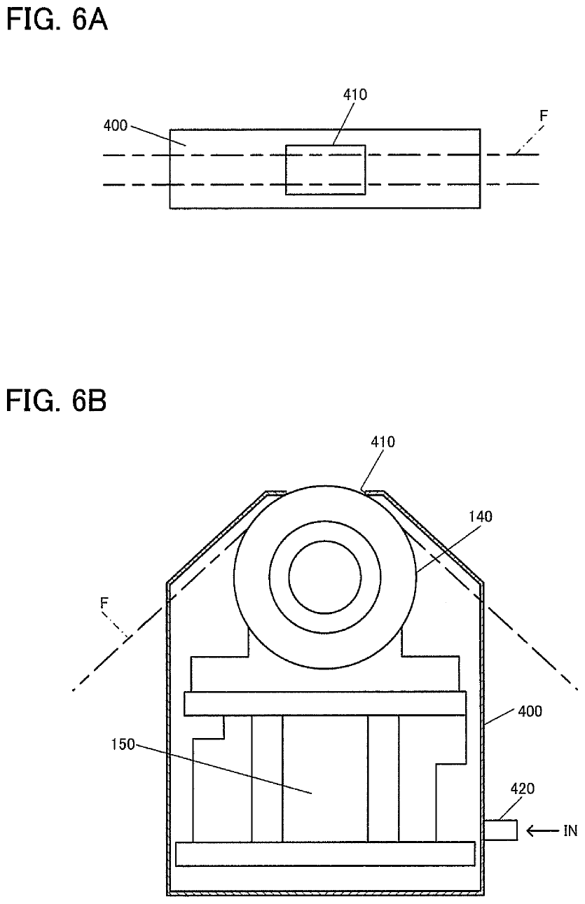

Therefore, a case 400 illustrated in FIG. 6A and FIG. 6B is arranged. The case 400 includes a slit 410 that allows part of a peripheral surface of the tension detection roller 140 to be exposed; and the case 400 surrounds the tension detection roller 140 except the part of the peripheral surface. In the case 400, a tension sensor 150 that detects tension based on external force acting on the tension detection roller 140 is also disposed. In addition, an inert gas such as Ar or N₂ is introduced into the case 400 at a pressure higher than a pressure in the chamber 10, through a gas supply pipe 420 coupled to the case 400.

As a result, a flow of an inert gas from inside the case 400 into the chamber 10 occurs and the film deposition gas does not enter the case 400. This prevents a failure of detection and erroneous detection that can be caused by film deposition on the tension detection roller 140 or the tension sensor 150, thereby ensuring a smooth supply of the long film F.

Although the embodiment has been described in detail above, those skilled in the art will readily appreciate that many modifications are possible without materially departing from the novel teachings and advantages of the disclosure. Accordingly, all such modifications are intended to be included within scope of this disclosure. For example, in the description or drawings, a term described together with a different term having wider meaning or the same meaning at least once can be replaced with the different term at any portion of the description or drawings. In addition, all combinations of the embodiment and the modifications are also included within the scope of the disclosure.

What is claimed is:

1. A film deposition apparatus, comprising:
a chamber having a film deposition gas introduced thereinto and exhausted therefrom, wherein film deposition with the film deposition gas is performed on an object to be treated; and
a film conveying part disposed in the chamber and conveying a long film in a roll-to-roll manner, the long film being the object to be treated;
wherein,
the film conveying part includes:
a rotatable roller, the long film coming into contact with part of a peripheral surface of the roller; and
a nozzle pipe for spraying an inert gas onto a region of the roller, the region being not covered by the long film.

2. The film deposition apparatus according to claim 1, wherein
the film conveying part further includes:
a bearing part rotatably supporting a shaft of the roller; and
a heater raising a temperature of the bearing part to a temperature not allowing the film deposition gas to be adhered to the shaft.

3. The film deposition apparatus according to claim 1, wherein
the film conveying part further includes:
a rotatable tension detection roller, the long film coming into contact with part of a peripheral surface of the tension detection roller;
a tension sensor detecting tension based on external force acting on the tension detection roller; and
a case including a slit, the slit having the part of the peripheral surface of the tension detection roller exposed, and surrounding both the tension detection roller except the part of the peripheral surface and the tension sensor;
wherein,
into the case, an inert gas is introduced at a pressure higher than a pressure in the chamber.

4. A film deposition apparatus, comprising:
a chamber having a film deposition gas introduced thereinto and exhausted therefrom, wherein film deposition with the film deposition gas is performed on an object to be treated; and
a film conveying part disposed in the chamber and conveying a long film in a roll-to-roll manner, the long film being the object to be treated;
wherein,
the film conveying part includes:
a rotatable roller, the long film coming into contact with part of a peripheral surface of the roller;
a bearing part rotatably supporting a shaft of the roller; and
a heater raising a temperature of the bearing part to a temperature not allowing the film deposition gas to be adhered to the shaft.

5. A film deposition apparatus, comprising:
a chamber having a film deposition gas introduced thereinto and exhausted therefrom, wherein film deposition with the film deposition gas is performed on an object to be treated;
a film conveying part disposed in the chamber and conveying a long film in a roll-to-roll manner, the long film being the object to be treated;
wherein,
the film conveying part includes:
a rotatable tension detection roller, the long film coming into contact with part of a peripheral surface of the tension detection roller;
a tension sensor detecting tension of the long film based on external force acting on the tension detection roller; and
a case including a slit, the slit having the part of the peripheral surface of the tension detection roller exposed, and surrounding both the tension detection roller except the part of the peripheral surface and the tension sensor;
wherein,
into the case, an inert gas is introduced at a pressure higher than a pressure in the chamber.
